(19) United States
(12) Patent Application Publication
(10) Pub. No.: US 2020/0195259 A1
(43) Pub. Date: Jun. 18, 2020

(54) LOW JITTER DIGITAL PHASE LOCK LOOP WITH A NUMERICALLY-CONTROLLED BULK ACOUSTIC WAVE OSCILLATOR

(71) Applicant: TEXAS INSTRUMENTS INCORPORATED, Dallas, TX (US)

(72) Inventor: Ben-yong ZHANG, Auburn, WA (US)

(21) Appl. No.: 16/511,107

(22) Filed: Jul. 15, 2019

Related U.S. Application Data
(60) Provisional application No. 62/779,635, filed on Dec. 14, 2018.

(51) Int. Cl. H03L 7/099; H03L 7/093; H03L 7/197; H03B 5/32; H03B 1/04

(52) U.S. Cl. CPC H03L 7/099; H03L 7/093; H03B 2200/004; H03B 5/326; H03B 1/04; H03L 7/1974

(57) ABSTRACT

A digital phase-locked loop (DPLL) includes a time-to-digital converter (TDC) having a first clock input, a second clock input, and a TDC output. The DPLL includes a digital loop filter (DLF). The DLF output controls a numerically-controlled bulk acoustic wave oscillator (NCBO). The NCBO output is divided down a fractional-N divider and is fed back to the TDC. The NCBO includes a reference oscillator, a phase and/or frequency detector, a charge pump, a loop filter, a voltage-controlled bulk acoustic wave oscillator (VCBO) and a feedback fractional-N divider that has a numerical control input, which is controlled by DLF output of DPLL. The NCBO forms a stable feedback loop and have a loop bandwidth much wider than DPLL loop bandwidth. In steady state, the NCBO output frequency can be linearly numerically adjusted. An auxiliary PLL or a fractional output divider can be used to generate additional needed frequencies.

### CROSS-REFERENCE TO RELATED APPLICATIONS

This application claims priority to U.S. Provisional Application No. 62/779,635, filed Dec. 14, 2018, which is hereby incorporated by reference in its entirety.

### BACKGROUND

In contemporary communication network equipment such routers and switchers, network synchronizers are used to generate and distribute output clocks for various sub-systems based on received network clocks. Because the received network reference clocks are typically noisy, narrow band phase-locked loops (PLL) are typically used to filter out received network reference clock noise. It is well-known that digital phase-locked loops (DPLL), which include components such as a time-to-digital converter (TDC), a digital loop filter (DLF), and a numerically-controlled oscillator (NCO), can achieve flexible programmable loop bandwidth and achieve very low loop bandwidth such as less than 1 mHz. DPLLs can also be used to easily implement other needed features for network synchronizers such as hitless input clock switching, phase buildout mode, holdover mode, etc. Given these benefits, DPLLs are widely used in network synchronizers.

One performance parameter of a network synchronizer is its output clock jitter, which is typically measured as the root mean square (rms) jitter integrated over a given frequency band such as from 12 kHz to 20 MHz. Reducing network synchronizer output clock jitter improves network bit error rate (BER), data rate (DR), and quality of service (QoS). The required network synchronizer output clock jitter specifications become more and more challenging as communication network data rates continue to increase, driven by heavy data traffic from applications such as wireless mobile internet, high speed video streaming, etc. For example, the maximum rms jitter (integrated over 12 KHz to 20 MHz) may be 1 ps for a 1 gigabits per second (GSPS) network, 500 fs for a 10 GSPS network, and 300 fs for 25 GSPS network. The current 100 GSPS network and future 400 GSPS networks require total rms jitter to be between 100 and 150 fs or less. It is becoming more and more difficult to meet such requirements for conventional network synchronizers.

### SUMMARY

A digital phase-locked loop (DPLL) includes a time-to-digital converter (TDC) having a first clock input, a second clock input, and a TDC output. The DPLL also includes a digital loop filter (DLF) having an input coupled to the TDC output, and having a DLF output. The DLF output controls a numerically-controlled bulk acoustic wave (BAW) oscillator (NCBO), which drives in TDC feedback input. The NCBO comprises a reference oscillator, a reference divider, a phase and/or frequency detector, a charge pump, a loop filter, a voltage-controlled bulk acoustic wave oscillator (VCBO), and a feedback fractional-N counter with numerical control input. The VCBO is locked to the reference oscillator. The NCBO output frequency is modulated by the numerical control input. The output clocks are generated from NCBO output. An auxiliary PLL or a low jitter fractional output divider may be used to generate additional output clock frequencies.

### BRIEF DESCRIPTION OF THE DRAWINGS

For a detailed description of various examples, reference will now be made to the accompanying drawings in which:

FIG. 1 shows an example of a bulk acoustic wave (BAW) resonator.

FIG. 2 shows an example of a voltage-controlled BAW resonator (VCBO).

FIG. 3 shows an example of a DPLL with a numerically controlled BAW oscillator (NCBO).

FIG. 4 shows an example of a network synchronizer which includes a digital phase-locked loop having an NCBO.

FIG. 5 includes plots of phase noise versus frequency for a digital phase-locked loop having an NCBO and for a conventional digital phase-locked loop

### DETAILED DESCRIPTION

For a DPLL-based network synchronizer, low output clock jitter can be achieved by implementing a low jitter numerically-controlled oscillator (NCO). In this disclosure, a numerically-controlled BAW oscillator (NCBO) is disclosed to achieve ultra-low jitter at, for example, a network synchronizer output. The disclosed NCBO comprises a reference oscillator, a phase/frequency detector, a charge pump, loop filter, a voltage-controlled BAW oscillator, a feedback fractional-N counter with numerical control input. Not only is ultra-low jitter achieved with this architecture, but other benefits are realized as well such as: i). the system works with low cost and low frequency (less than 50 MHz) reference oscillators such as low frequency oven-stabilized crystal oscillators (OCXO), temperature compensated crystal oscillators (TCXO), or ordinary crystal oscillators (XO); and ii) mid-band (from 10 kHz to 1 MHz) phase noise is improved.

One drawback of this disclosed NCBO based network synchronizer is that it can only generate one frequency at the NCBO output. If an integer divider is used to divide down the NCBO output to generate output clocks, the generated output frequencies are limited and may be unable to generate needed frequencies for the entire system. An auxiliary PLL can be used to generate additional frequencies, or a low jitter fractional output divider may be used.

Digital phase-locked loops (DPLLs), which typically comprise a time-to-digital converter (TDC), a digital loop filter (DLF), and a numerically controlled oscillator (NCO), are widely used in network synchronizers. Because typical DPLL loop bandwidth is narrw (less than a few kilo-Hertz), its root mean square (rms) jitter performance is mainly determined by its NCO. A numerically-controlled oscillator (NCO) comprises a reference oscillator, an analog phase-locked loop (APLL) including a frequency or phase-frequency detector, a loop filter, a voltage-controller oscillator (VCO), and a fractional feedback frequency divider with a numerical control input. Increasing the bandwidth of the loop filter advantageously attenuates VCO closed-in phase noise, and thereby reduces NCO total rms jitter. However, the loop bandwidth should not be too large, otherwise APLL inherent in-band phase noise or reference oscillator phase noise may become the dominant contributor to total NCO rms jitter beyond the loop bandwidth thereby resulting in an increase of total NCO rms jitter. Meeting ultra-low target values for total rms jitter (e.g., less than 100 fs) is a challenge.

For a conventional DPLL network synchronizer, the VCO is implemented using an LC (inductor and capacitor) circuit. Its LC VCO phase noise is limited by an inherent low quality factor of integrated inductor. The NCO loop bandwidth that gives optimum total output clock jitter is typically several hundred KHz. With such wide NCO loop bandwidth, the reference oscillator noise and APLL inherent inband phase noise are important contributors to total NCO output jitter thus limiting the achievable total rms jitter.

The NCBO-based network synchronizer described herein, however, includes a bulk acoustic wave (BAW) resonator integrated into the integrated circuit (IC) package with the rest of the components of the network synchronizer. The BAW resonator is used to implement an ultra-low phase noise numerically-controlled BAW oscillator (NCBO), permitting achieving ultra-low rms jitter, such as sub-100 fs total rms jitter integrated over the frequency range of 12 KHz to 20 MHz.

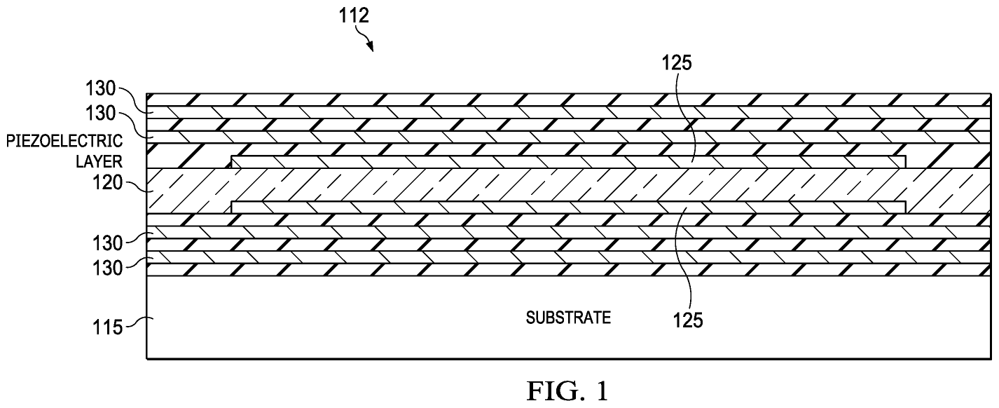

FIG. 1 shows an example of a BAW resonator 112, which provides a stable, high-Q resonant element. The BAW resonator 112 in the example of FIG. 1 includes a piezoelectric layer 120 sandwiched between electrodes 125. The BAW resonator 112 also includes stacked reflector layers 130 which confine mechanical energy within the resonator. The BAW resonator is formed on a substrate 115.

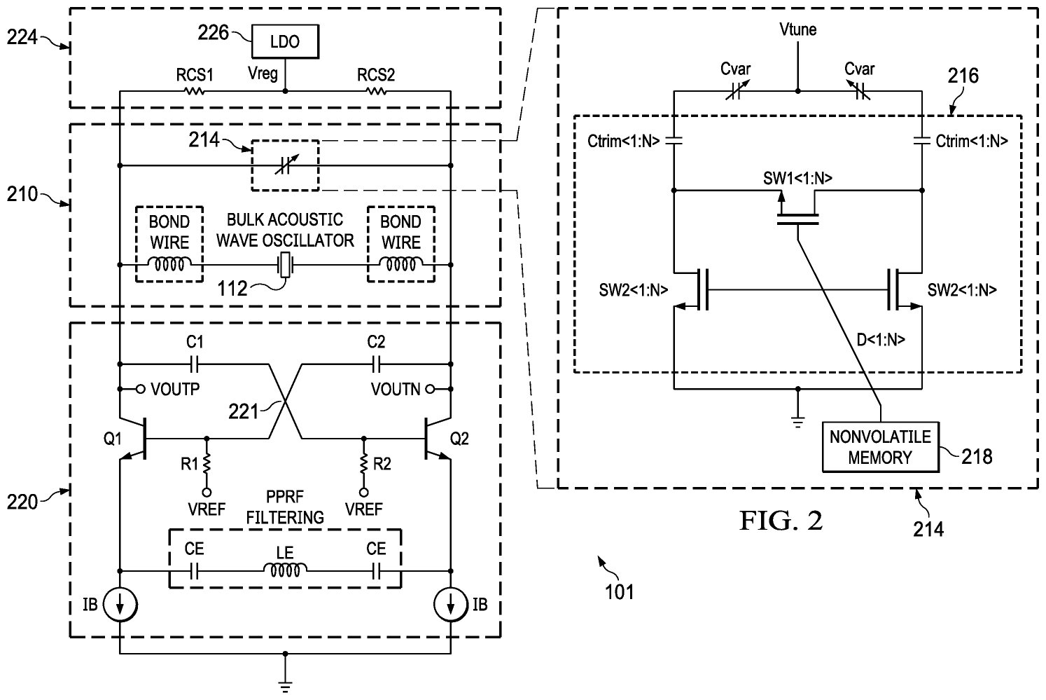

FIG. 2 illustrates an example VCBO 101. The VCBO 101 in the example of FIG. 1 includes an active oscillator core with a BAW oscillator 210 and a differential negative transconductance (gm) oscillation driver 220. BAW oscillator 210 includes a BAW resonator 112 and a voltage-controlled variable load capacitance 214. The example variable load capacitance 214 is implemented with dual varactors Cvar, controlled by a Vtune control voltage. Coarse capacitance adjustment is provided by a switched coarse capacitor array 216 including capacitors Ctrim switched by a switch network SW1/SW2 controlled by ta rim code stored in nonvolatile memory (NVM) 218.

The varactors Cvar and the switched coarse capacitor array 216 provide high-Q tuning load capacitance for the BAW oscillator 210. The trim code (control word) for switched coarse capacitor array can be determined during factory calibration and the result is stored in NVM 218. Using this coarse capacitance trim approach, the target frequency of VCBO can be trimmed within tens of parts per million in the manufacturing process, avoiding digital coarse calibration, and improving oscillator lock time.

The varactors Cvar can be controlled by an analog tuning voltage Vtune, which provides sufficient pull-in range to compensate for frequency shift/deviation caused by factors such as residue error from factory calibration, temperature, and power supply variations, as well as BAW resonator aging. The varactors Cvar can be designed so that the VCBO can meet specified APR (absolute pull range) specifications such as +/−50 ppm. For an NCBO implementation such as described below, the Vtune control voltage can be provided by an APLL loop filter driven by its phase-frequency detector (PFD) charge pump (CP). Refer to previous patent application on more details of the VCBO.

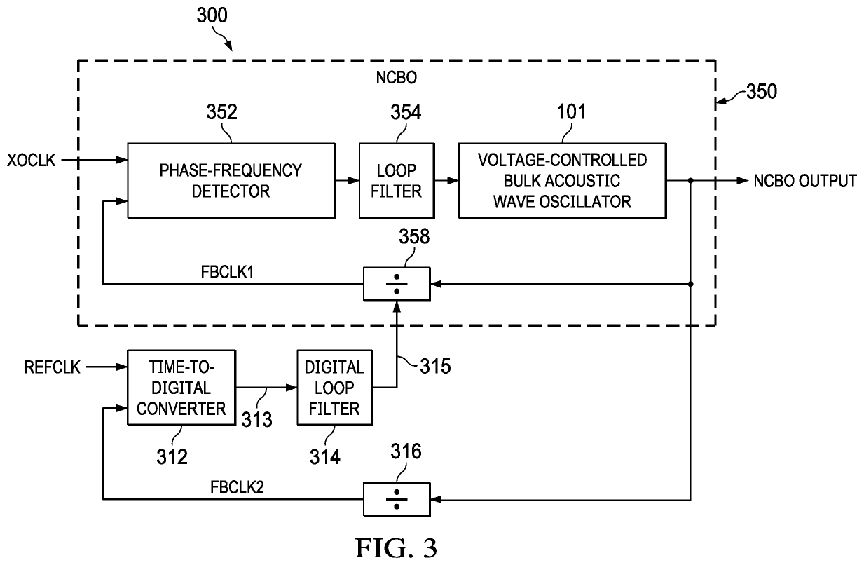

FIG. 3 shows an example of a DPLL 300 with a numerically-controlled BAW oscillator (NCBO) 350. The DPLL 300 includes a time-to-digital converter (TDC) 312, a digital loop filter (DLF) 314, the NCBO 350, and a feedback fractional-N frequency divider 316. The NCBO 350 includes a reference oscillator, a PFD/charge pump 352, a loop filter (LF) 354, a voltage-controlled BAW oscillator (VCBO) 101, and a programmable fractional-N frequency divider 358. Additional components may be included as well in other examples. The PFD 352 detects the phase and/or frequency difference between a reference oscillator (e.g., XOCLK) and a feedback clock (FBCLK1). FBCLK1 is generated by the programmable frequency divider 358 and is a divided down version of the VCBO 101 output. The PFD 352 generates an output control signal to the LF 354 based on the phase and/or frequency difference. The LF 354 filters the PFD's output control signal. The filtered output from the LF 354 is the Vtune voltage for the VCBO 101, as shown in FIG. 2. The VCBO 101 includes a BAW resonator, such as that shown in FIG. 1. The NCBO 350 implements a feedback control loop in which the NCBO output is fed back to the PFD 352 via the frequency divider 358, and a voltage is generated to adjust the frequency of the NCBO output. As such, the frequency of the NCBO output is continually adjusted, as necessary, to maintain phase lock. In steady state, the frequency of NCBO can be calculated as Fncbo=Fosc/R*(N+(Num+Nctrl)/Den), where Fosc is the reference oscillator frequency, R is the reference divide ratio, N is the integer portion of the fractional-N divider, Den is the denominator of the fractional-N divider, Num is the nominal numerator value of fractional-N divider, and Nctrl is the numerical control input of the NCBO. The NCBO output frequency can be tuned by adjusting the Nctl value.

The TDC 312 of the DPLL 300 determines the phase difference between the reference clock (REFCLK) and feedback clock (FBCLK2). FBCLK2 is derived from the NCBO output via a fractional-N frequency divider 316. The TDC 312 generates a digital correction word 313 corresponding to the phase error between REFCLK and FBCLK2. The correction word 313 is filtered by DLF 314, and the frequency control word Nctrl 315 from the DLF 314 is used to control the divide ratio of the programmable frequency divider 358 within the NCBO 350.

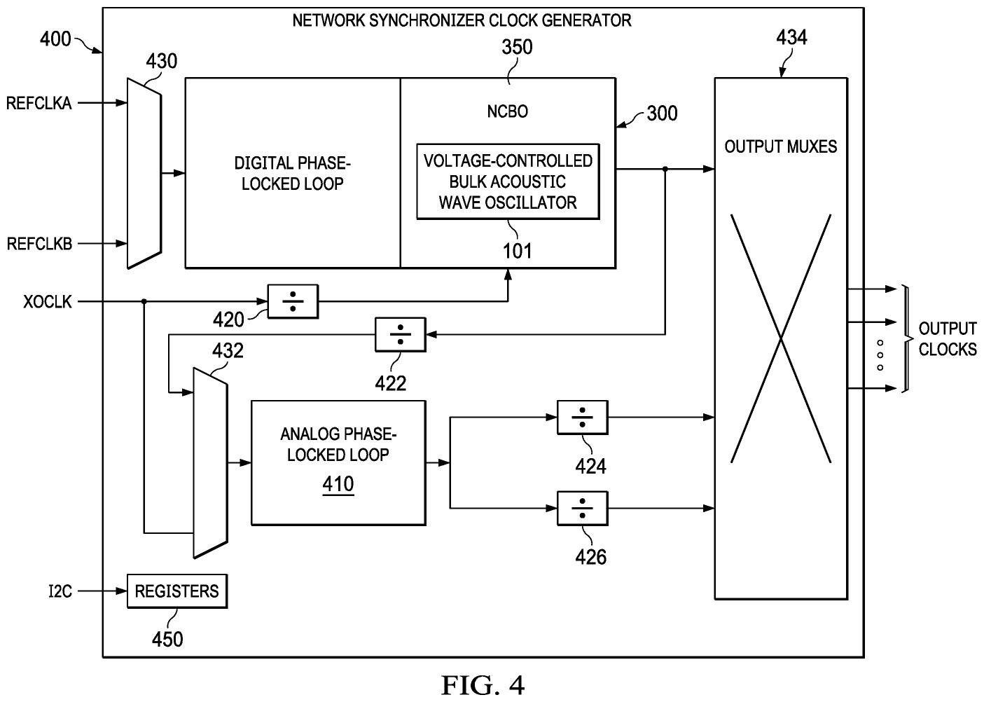

FIG. 4 shows an example implementation of a network synchronizer clock generator 400 including DPLL 300, which itself includes NCBO 101 as described above. The components of the example network synchronizer clock generator 400 shown in FIG. 4 are fabricated on the same semiconductor die and thus the network synchronizer 400 is a single IC. In addition to the DPLL 300, the network synchronizer clock generator 400 includes an auxiliary APLL 410, frequency dividers 420, 422, 4224, and 426, multiplexers 430, 432 and 434, registers/non-volatile memory (NVM) 450. One or more input reference clocks (e.g., REFCLKA and REFCLKB) are provided to inputs of multiplexer 430, which selects one of its input reference clocks to provide to PLL 300. The reference oscillator XOCLK is provided via a frequency divider 420 to the NCBO 350 within DPLL 300, and to an input of multiplexer 432. The output clock from NCBO 350 is provided to the output multiplexers 434 and to frequency divider 422. The output of the frequency divider 422 is provided to another input of multiplexer 432, the output of which is provided as the reference clock input to auxiliary APLL 410.

The auxiliary APLL 410 in this example includes an LC-based VCO. The main purpose of the auxiliary APLL 410 is to generate additional clock frequencies that cannot be generated from the single NCBO frequency (e.g., 2.5 GHz) using an integer output divider. The output of the APLL 410 is divided down via two programmable, post dividers 424 and 426, the outputs of which are provided o the output multiplexers 434.

The registers 450 are usable to store configuration parameters for the operation of the network synchronizer clock generator 400. The configuration parameters may include, for example, calibrated VCBO parameters, frequency divide ratios for those frequency dividers that are programmable, etc. The network synchronizer clock generator 400 includes a serial interface such as the inter-integrated circuit (I2C) interface to receive configuration parameters for storage into registers 450.

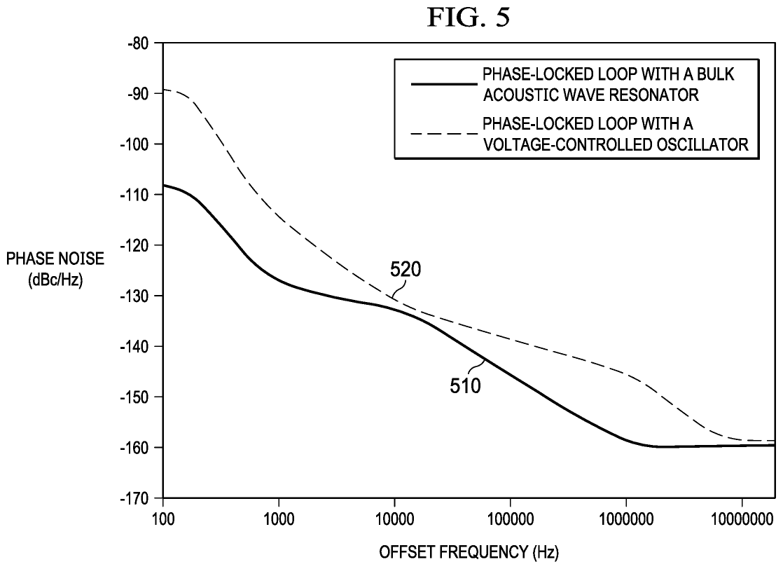

By using an NCBO within the DPLL 300, the total rms jitter is significantly lower than for a conventional DPLL. In one example, at a DPLL clock output having a frequency of 312.5 MHz, the typical total rms jitter integrated over the frequency range from 12 KHz to 20 MHz is approximately 47 fs. FIG. 5 shows an example of phase noise versus frequency for a PLL using an NCBO (plot 510) and a conventional DPLL (plot 520). Due to the superior phase noise of the BAW oscillator, ultra-low rms jitter (less than 100 fs) can be achieved with an NCBO bandwidth of a few KHz. Also, as can be seen, the mid-band phase noise (10 KHz to 1 MHz) is much better when using an NCBO than a conventional DPLL. The lower phase noise of a DPLL with an NCBO is particularly advantageous for those systems that require stringent clock phase noise at certain frequency offsets within mid-band.

Further, because the NCBO loop bandwidth is around several kilo-Hertz, phase noise from the external reference oscillator XOCLK is less critical for total rms jitter integrated from 12 kHz to 20 MHz, a lower cost lower frequency crystal oscillator or TCXO or OCXO (e.g., less than 50 MHz) can be used to drive the NCBO 350 within the DPLL 300, thereby lowering the cost of the solution as well. As a comparison, to achieve satisfactory jitter performance, a higher frequency higher cost XOCLK (e.g., 52 MHz or higher) may be required for a conventional DPLL.

Another advantage for a DPLL having an NCBO relates to fractional-spur and quantization noises filter. With a NCBO loop bandwidth of around several KHz, it is much easier to filter out fractional spurs and fractional PLL quantization noises using a DPLL with an NCBO than with a conventional DPLL thereby resulting in output clocks with low spurious components.

In this description, the term “couple” or “couples” means either an indirect or direct wired or wireless connection. Thus, if a first device couples to a second device, that connection may be through a direct connection or through an indirect connection via other devices and connections. The recitation “based on” means “based at least in part on.” Therefore, if X is based on Y, X may be a function of Y and any number of other factors. Modifications are possible in the described embodiments, and other embodiments are possible, within the scope of the claims.

What is claimed is:

1. A digital phase-locked loop (DPLL), comprising:
a time-to-digital converter (TDC) having a first clock input, a second clock input, and a TDC output;
a digital loop filter (DLF) having an input coupled to the TDC output, and having a DLF output; and
a numerically-controlled bulk acoustic wave oscillator (NCBO), comprising:
a phase detector having an output;
a loop filter coupled to the output of the phase detector;
a voltage-controlled bulk acoustic wave oscillator (VCBO) coupled to the loop filter, the VCBO having a VCBO output; and
a feedback fractional-N divider with a numerical control input.

2. The DPLL of claim 1, wherein the NCBO includes a bulk acoustic wave (BAW) resonator.

3. The DPLL of claim 2, wherein the VCBO includes a capacitor array including at least first and second capacitors coupled to respective terminals of the BAW resonator.

4. The DPLL of claim 2, further including an oscillator driver coupled to the BAW resonator to provide an oscillator drive signal.

5. The DPLL of claim 1, further including a second frequency divider coupled between the VCBO output and the TDC.

6. The DPLL of claim 1, wherein the feedback fractional-N frequency divider is configurable by the DLF output.

7. The DPLL of claim 1, wherein the phase detector is a phase and frequency detector.

8. A network synchronizer, comprising:
a digital phase-locked loop (DPLL) including a numerically-controlled bulk acoustic wave (BAW) oscillator (NCBO),
an auxiliary PLL having a second PLL output; and
an output multiplexer coupled to the first PLL output and to the second PLL output, the output multiplexer having a multiplexer output.

9. The network synchronizer of claim 8, wherein the DPLL includes a digital loop filter (DLF) having a DLF output, and wherein the NCBO includes a frequency divider that is configured to be controlled by the DLF output.

10. The network synchronizer of claim 8, wherein the DPLL, the auxiliary PLL, and the output multiplexer are provided on a same semiconductor die.

11. The network synchronizer clock generator of claim 8, further including a variable load capacitance coupled to the BAW oscillator.

12. The network synchronizer of claim 8, further including a capacitor array including at least first and second capacitors coupled to respective terminals of the BAW oscillator.

13. The network synchronizer of claim 8, further including an oscillator driver coupled to the BAW oscillator to provide an oscillator drive signal for the BAW oscillator.

14. The network synchronizer of claim 8, further wherein the DPLL, the auxiliary PLL, and the output multiplexer are provided on a same semiconductor die.
